(19) United States
(12) Patent Application Publication
(10) Pub. No.: US 2025/0210487 A1
(43) Pub. Date: Jun. 26, 2025

(54) SEMICONDUCTOR PACKAGE

(71) Applicant: Samsung Electronics Co., Ltd., Suwon-si (KR)

(72) Inventors: Hyeonjeong Hwang, Suwon-si (KR); Jihwang Kim, Suwon-si (KR); Kuwon Lee, Suwon-si (KR)

(21) Appl. No.: 18/976,793

(22) Filed: Dec. 11, 2024

(30) Foreign Application Priority Data
Dec. 21, 2023 (KR) 10-2023-0188651

(51) Int. Cl. H01L 23/498; H01L 23/00; H01L 23/31; H01L 23/367; H01L 23/544; H01L 25/10; H01L 25/18; H10B 80/00

(52) U.S. Cl. CPC H01L 23/49822; H01L 23/3128; H01L 23/3672; H01L 23/49833; H01L 23/49838; H01L 23/544; H01L 24/16; H01L 24/48; H01L 24/73; H01L 25/105; H01L 24/06; H01L 24/32; H01L 25/18; H01L 2223/54406; H01L 2223/54413; H01L 2224/06131; H01L 2224/16227; H01L 2224/16238; H01L 2224/32225; H01L 2224/48225; H01L 2224/73204; H01L 2224/73257; H01L 2224/73265; H01L 2225/1041; H01L 2225/1094; H01L 2924/19011; H10B 80/00

(57) ABSTRACT

A semiconductor package includes a first molding member, a redistribution structure, a mark metal layer, and a mesh metal layer. The first molding member covers at least one first semiconductor chip. The redistribution structure is provided on the first molding member and includes a redistribution pattern, an upper pad, and a redistribution insulating layer. The mark metal layer is provided on the redistribution structure. The mesh metal layer is provided on a lower surface of the mark metal layer and includes at least one hole.

### CROSS-REFERENCE TO RELATED APPLICATION

This application is based on and claims priority under 35 U.S.C. § 119 to Korean Patent Application No. 10-2023-0188651, filed on Dec. 21, 2023, in the Korean Intellectual Property Office, the disclosure of which is incorporated by reference herein in its entirety.

### BACKGROUND

The inventive concept relates to a semiconductor package, and more particularly, to a semiconductor package including a mark.

Recently, in the electronic product market, demand for portable devices has rapidly increased, and thus, electronic components of electronic products have been constantly required to be small and lightweight. For the miniaturization and weight-reduction of electronic components, semiconductor packages mounted on electronic components are also required to have a small volume while having the ability to process a large amount of data.

In addition, marks indicating product information may be provided on surfaces of semiconductor packages including semiconductor chips. However, as the thickness of semiconductor packages reduces, issues arise regarding the structural reliability and thermal characteristics of semiconductor packages that include marks within certain layers such as metal layers.

### SUMMARY

The inventive concept provides a semiconductor package with improved structural reliability and thermal characteristics.

Aspects of the inventive concept are not limited to the aforesaid, and other aspects of the inventive concept will be understood by those skilled in the art through the following description.

Aspects of the inventive concept are provided in the following semiconductor packages.

According to an aspect of the inventive concept, there is provided a semiconductor package including a first molding member, a redistribution structure, a mark metal layer, and a mesh metal layer. The first molding member covers at least one first semiconductor chip. The redistribution structure is provided on the first molding member and includes a redistribution pattern, an upper pad, and a redistribution insulating layer. The mark metal layer is provided on the redistribution structure. The mesh metal layer is provided on a lower surface of the mark metal layer and includes at least one hole.

According to another aspect of the inventive concept, there is provided a semiconductor package including a first redistribution structure, a first semiconductor chip, a first molding member, a second redistribution structure, a mark metal layer, a mesh metal layer, and a heat-conducting via. The first redistribution structure includes a first redistribution pattern configured to transmit an electrical signal, and a first redistribution insulating layer surrounding the first redistribution pattern. The first semiconductor chip is mounted on the first redistribution structure. The first molding member surrounds the first semiconductor chip. The second redistribution structure includes a second redistribution pattern configured to transmit an electrical signal, a second redistribution insulating layer surrounding the second redistribution pattern, and an upper pad exposed upward on the second redistribution insulating layer in a vertical direction. The second redistribution structure is provided on an upper surface of the first molding member. The mark metal layer is provided on the second redistribution structure. The mesh metal layer is provided on a lower surface of the mark metal layer and includes at least one hole. The heat-conducting via is provided on a lower surface of the mesh metal layer and physically connects the mesh metal layer and the second redistribution pattern to each other.

According to another aspect of the inventive concept, there is provided a semiconductor package including a first redistribution structure, a first semiconductor chip, a conductive pillar, a first molding member, a second redistribution structure, a mark metal layer, a mesh metal layer, and a heat-conducting via. The first redistribution structure includes a first redistribution pattern configured to transmit an electrical signal, and a first redistribution insulating layer surrounding the first redistribution pattern. The first semiconductor chip is mounted on the first redistribution structure. The conductive pillar is provided on the first redistribution structure apart from the first semiconductor chip in a horizontal direction. The first molding member surrounds each of the first semiconductor chip and the conductive pillar. The second redistribution structure includes a second redistribution pattern configured to transmit an electrical signal, a second redistribution insulating layer surrounding the second redistribution pattern, and an upper pad exposed upward on the second redistribution insulating layer in a vertical direction. The second redistribution structure is provided on an upper surface of the first molding member. The mark metal layer is provided on the second redistribution structure and includes a mark on an upper surface thereof, and the mark includes at least one selected from the group consisting of letters, numbers, and identification codes. The mesh metal layer is provided on a lower surface of the mark metal layer and includes at least one hole. The heat-conducting via is provided on a lower surface of the mesh metal layer and physically connects the mesh metal layer and the second redistribution pattern to each other. The second redistribution insulating layer includes a plurality of second redistribution insulating layers stacked in the vertical direction, and the heat-conducting via is formed in an uppermost second redistribution insulating layer among the plurality of second redistribution insulating layers. Each of the mesh metal layer and the mark metal layer overlaps the first semiconductor chip in the vertical direction.

### BRIEF DESCRIPTION OF THE DRAWINGS

Embodiments will be more clearly understood from the following detailed description taken in conjunction with the accompanying drawings in which:

FIG. 1 is a cross-sectional view illustrating a semiconductor package according to an embodiment;

FIG. 2 is a plan view illustrating the semiconductor package shown in FIG. 1;

FIG. 3 is an enlarged cross-sectional view illustrating a mark formed on a mark metal layer of the semiconductor package shown in FIGS. 1 and 2;

FIG. 4 is a plan view illustrating the mark shown in FIG. 3;

FIG. 5 is a plan view illustrating a mesh metal layer of the semiconductor package shown in FIGS. 1 and 2;

FIG. 6 is a cross-sectional view illustrating a semiconductor package according to an embodiment;

FIG. 7 is a cross-sectional view illustrating a semiconductor package according to an embodiment;

FIG. 8 is a cross-sectional view illustrating a semiconductor package according to an embodiment;

FIG. 9 is a schematic block diagram illustrating an example of a memory system including a semiconductor package according to an embodiment; and

FIG. 10 is a schematic block diagram illustrating an example of an information processing system including a semiconductor package according to an embodiment.

### DETAILED DESCRIPTION OF THE EMBODIMENTS

Hereinafter, embodiments will be described with reference to the accompanying drawings. In the drawings, like reference numerals denote like elements, and repeated descriptions thereof are omitted.

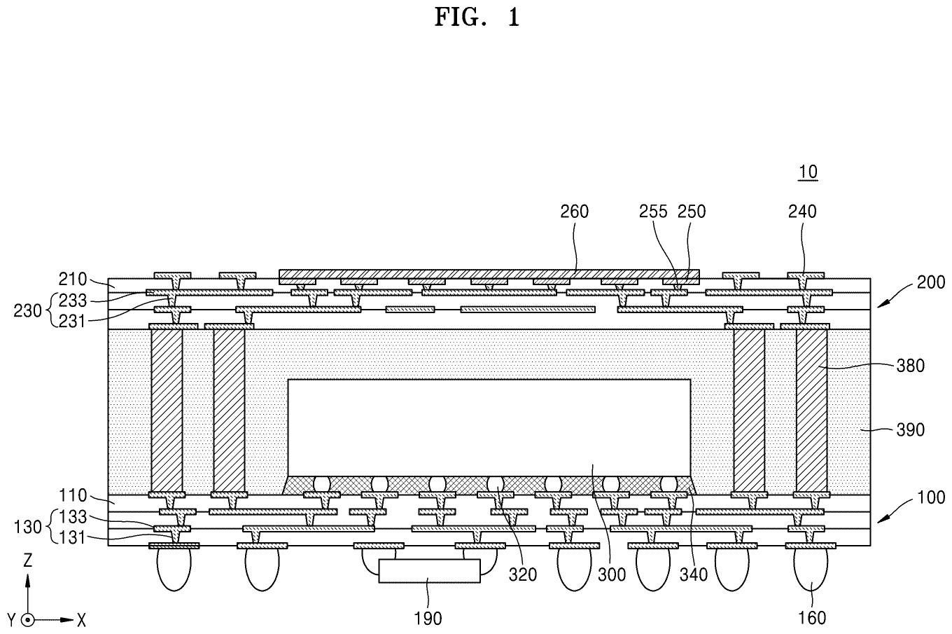

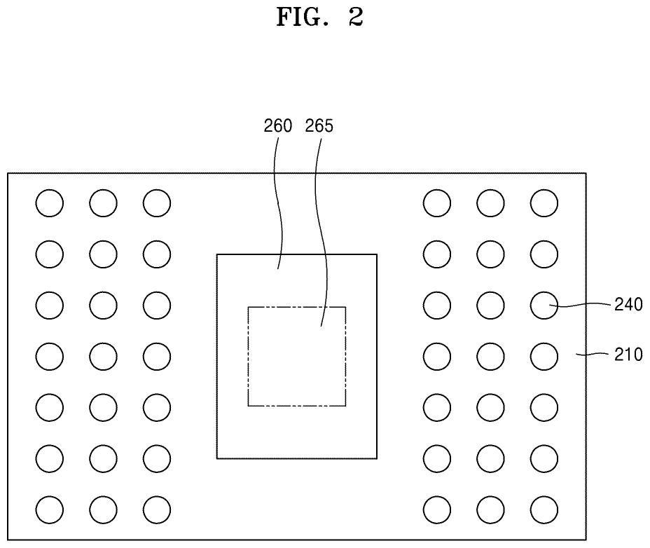

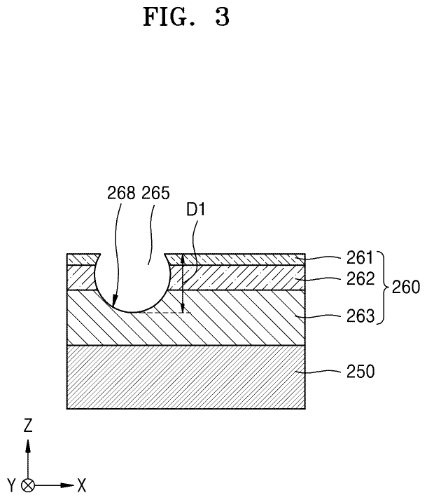

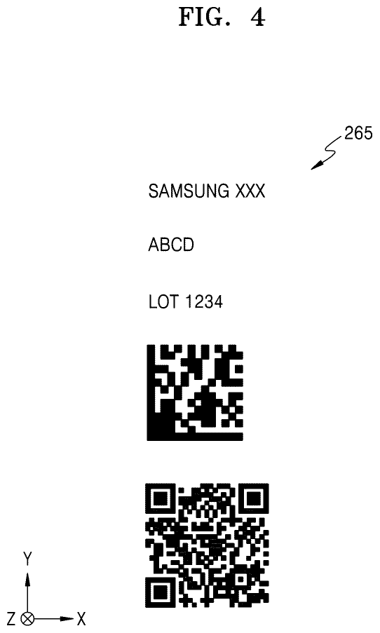

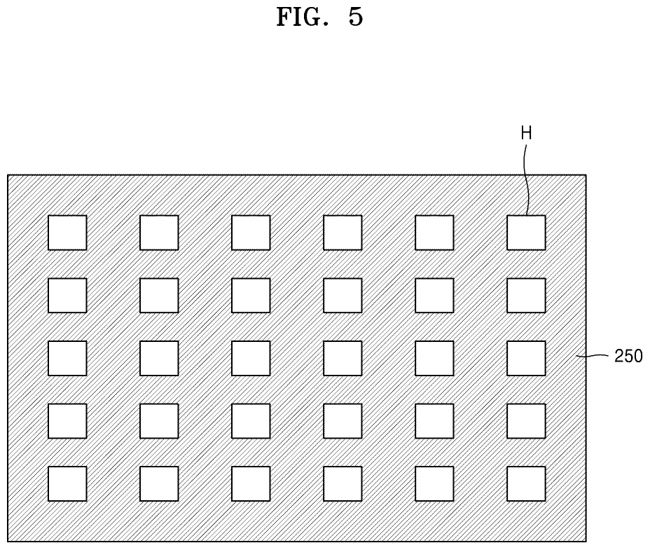

FIG. 1 is a cross-sectional view illustrating a semiconductor package 10 according to an embodiment. FIG. 2 is a plan view illustrating the semiconductor package 10 shown in FIG. 1. FIG. 3 is an enlarged cross-sectional view illustrating a mark 265 formed on a mark metal layer 260 of the semiconductor package 10 shown in FIGS. 1 and 2. FIG. 4 is a plan view illustrating the mark 265 shown in FIG. 3. FIG. 5 is a plan view illustrating a mesh metal layer 250 of the semiconductor package 10 shown in FIGS. 1 and 2.

FIGS. 1 to 5, the semiconductor package 10 of the inventive concept may include a first redistribution structure 100, a first semiconductor chip 300, a first molding member 390, a second redistribution structure 200, the mesh metal layer 250, and the mark metal layer 260.

The first redistribution structure 100 may include upper and lower surfaces that are opposite each other, and at least one of the upper and lower surfaces may be flat. The first redistribution structure 100 is disposed below the first semiconductor chip 300 and may electrically connect the first semiconductor chip 300 to external connection bumps 160. The first redistribution structure 100 may include a first redistribution insulating layer 110 and a first redistribution pattern 130.

The first redistribution insulating layer 110 may include a plurality of layers stacked in one direction, and the first redistribution pattern 130 may be formed penetrating the first redistribution insulating layer 110 from the upper surface to the lower surface of the first redistribution structure 100. Here, the first redistribution pattern 130 may serve as an electrical connection path penetrating the upper and lower surfaces of the first redistribution structure 100.

In the following drawings, a direction in which a plurality of insulating layers are stacked may be understood as a Z-axis direction, and an X-axis direction a Y-axis direction may be understood as directions perpendicular to each other in a plane having a normal vector in the Z-axis direction. That is, the X-axis direction and the Y-axis direction refer to directions parallel to the upper or lower surface of the first redistribution structure 100. The Z-axis direction may refer to a direction perpendicular to the upper or lower surface of the first redistribution structure 100, that is, a direction perpendicular to an X-Y plane. Furthermore, in the following drawings, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

The first redistribution pattern 130 may be electrically connected to a conductive pillar 380 and the first semiconductor chip 300. The first redistribution pattern 130 may include a first redistribution via pattern 131 and a first redistribution line pattern 133. The first redistribution line pattern 133 may have a shape extending in the first horizontal direction (X-axis direction) within the first redistribution insulating layer 110. According to embodiments, first redistribution line patterns 133 may be respectively provided on a plurality of first redistribution insulating layers 110 that are stacked in the vertical direction (Z-axis direction). The first redistribution via pattern 131 may extend in the vertical direction (Z-axis direction) and penetrate at least one first redistribution insulating layer 110 in the vertical direction (Z-axis direction). The first redistribution via pattern 131 may electrically connect the first redistribution line patterns 133 that are respectively formed on the plurality of first redistribution insulating layers 110.

In some embodiments, the first redistribution via pattern 131 may have a tapered shape extending with a horizontal width increasing in an upward direction. For example, the horizontal width of the first redistribution via pattern 131 may increase in a direction toward the first semiconductor chip 300. In some embodiments, the first redistribution via pattern 131 may have a tapered shape of which the horizontal width increases as the level of the first redistribution via pattern 131 decreases in the vertical direction (Z-axis direction). For example, the horizontal width of the first redistribution via pattern 131 may increase in a direction toward the external connection bumps 160.

According to embodiments, the first redistribution insulating layer 110 may include a photo imageable dielectric (PID) or photosensitive polyimide (PSPI), and the first redistribution pattern 130 may include a metal such as copper (Cu), aluminum (Al), tungsten (W), titanium (Ti), tantalum (Ta), indium (In), molybdenum (Mo), manganese (Metals or alloys of metals such as Mn), cobalt (Co), tin (Sn), nickel (Ni), magnesium (Mg), rhenium (Re), beryllium (Be), gallium (Ga), ruthenium (Ru), or an alloy thereof. However, embodiments are not limited thereto. In some embodiments, the first redistribution pattern 130 may be formed by stacking a metal or a metal alloy on a seed layer including copper, titanium, titanium nitride, or titanium tungsten. According to embodiments, the first redistribution line pattern 133 and the first redistribution via pattern 131 may be formed together as one pattern.

In some embodiments, the first redistribution structure 100 may be a printed circuit board (PCB). In this case, the first redistribution insulating layer 110 may include at least one material selected from the group consisting of a phenol resin, an epoxy resin, and polyimide. For example, the first redistribution insulating layer 110 may include at least one material selected from the group consisting of Flame Retardant 4 (FR-4), tetrafunctional epoxy, polyphenylene ether, epoxy/polyphenylene oxide, bismaleimide triazine (BT), Thermount, cyanate ester, polyimide, and a liquid crystal polymer. In addition, the first redistribution pattern 130 may include copper, nickel, stainless steel, or beryllium copper.

The external connection bumps 160 may be provided on a lower portion of the first redistribution structure 100. The external connection bumps 160 may be electrically connected to an external device, for example, a motherboard. The external connection bumps 160 may be electrically connected to the first redistribution pattern 130. The external connection bumps 160 may transmit, to the external device, electrical signals received from the first semiconductor chip 300 through the first redistribution pattern 130. The first redistribution pattern 130 may be electrically connected to the external device through the external connection bumps 160. The external connection bumps 160 may include a conductive material. For example, the external connection bumps 160 may include at least one selected from the group consisting of solder, tin (Sn), silver (Ag), copper (Cu), and aluminum (Al).

A passive device 190 may be disposed on the lower portion of the semiconductor device 100 apart from the external connection bumps 160 in the first horizontal direction (X-axis direction). According to embodiments, the passive device 190 may be connected to the first redistribution structure 100 through bumps. The passive device 190 may include, for example, a capacitor such as a multilayer ceramic capacitor (MLCC) or a low inductance chip capacitor (LICC), an inductor, a bead, or the like.

The first semiconductor chip 300 may be mounted on the upper surface of the first redistribution structure 100. The first semiconductor chip 300 may be electrically connected to the first redistribution pattern 130. According to embodiments, the first semiconductor chip 300 may be mounted on the first redistribution structure 100 by a flip chip method using chip connection bumps 320 such as micro-bumps. According to embodiments, an underfill material layer 340 surrounding the chip connection bumps 320 may be disposed between the first semiconductor chip 300 and the first redistribution structure 100. The underfill material layer 340 may be formed by, for example, a capillary underfill method using an epoxy resin. However, in some embodiments, the first molding member 390 may be directly filled in a gap between the first semiconductor chip 300 and the first redistribution structure 100 through a molded underfill process. In this case, the underfill material layer 340 may be omitted.

The first semiconductor chip 300 may include a memory chip or a logic chip. For example, the memory chip may be a volatile memory chip such as a dynamic random access memory (DRAM) chip or a static random access memory (SRAM) chip, or a non-volatile memory chip such as a phase-change random access memory (PRAM) chip, a magnetoresistive random access memory (MRAM) chip, a ferroelectric random access memory (FeRAM) chip, or a resistive random access memory (RRAM) chip. For example, the logic chip may be a microprocessor such as a central processing unit (CPU), a graphics processing unit (GPU), a microcontroller unit (MCU) having one or more CPUs, or an application processor (AP), an analog device, or a digital signal processor.

The first molding member 390 may be formed on the upper surface of the first redistribution structure 100 to surround the first semiconductor chip 300. In some embodiments, the first molding member 390 may cover lateral and upper surfaces of the first semiconductor chip 300.

The first molding member 390 may include: a thermosetting resin such as an epoxy resin; a thermoplastic resin such as polyimide; or a thermosetting or thermoplastic resin containing a reinforcing material such as an inorganic filler, for example, Ajinomoto Build-up Film (ABF), FR-4, or BT. However, the first molding member 390 is not limited thereto. In other embodiments, the first molding member 390 may include a molding material such as epoxy mold compound (EMC) or a photosensitive material such as photo imageable encapsulant (PIE). In some embodiments, a portion of the first molding member 390 may include an insulating material such as a silicon oxide film, a silicon nitride film, or a silicon oxynitride film.

The conductive pillar 380 may be positioned on the upper surface of the first redistribution structure 100 apart from the first semiconductor chip 300 in a horizontal direction. According to embodiments, a plurality of conductive pillars 380 may be provided. The conductive pillars 380 may be arranged apart from each other at predetermined intervals in the horizontal direction. The conductive pillars 380 may have a shape extending in the vertical direction (Z-axis direction) and may penetrate the first molding member 390 in the vertical direction (Z-axis direction).

The conductive pillars 380 may electrically connect the second redistribution structure 200 and the first redistribution structure 100 to each other. That is, the conductive pillars 380 may be vertical connection conductors through which the first redistribution structure 100 and the second redistribution structure 200 are electrically connected to each other. According to embodiments, the conductive pillars 380 may be through-mold vias or conductive posts. The conductive pillars 380 may include, for example, copper (Cu).

Upper surfaces of the conductive pillars 380 may be on the same plane as an upper surface of the first molding member 390. In some embodiments, the level of an upper surface of the first semiconductor chip 300 may be lower than the level the upper surface of the first molding member 390 in the vertical direction (Z-axis direction).

The second redistribution structure 200 may be disposed on the upper surface of the first molding member 390. The second redistribution structure 200 may include an upper surface and a lower surface that are opposite each other, and at least one of the upper surface and the lower surface may be flat. The second redistribution structure 200 may include a second redistribution pattern 230, a second redistribution insulating layer 210, and upper pads 240. The second redistribution insulating layer 210 may include a plurality of layers that are stacked in the vertical direction (Z-axis direction). The second redistribution pattern 230 may include a second redistribution via pattern 231 and a second redistribution line pattern 233. The upper pads 240 may be formed on a surface of the second redistribution structure 200 and may have a shape extending in the first horizontal direction (X-axis direction). The upper pads 240 may be provided apart from the mark metal layer 260 in the first or second horizontal direction (X-axis or Y-axis direction).

The second redistribution pattern 230 and the second redistribution insulating layer 210 are substantially the same as or similar to the first redistribution pattern 130 and the first redistribution insulating layer 110, and thus, repeated descriptions thereof are omitted.

The mark metal layer 260 may be disposed on the upper surface of the second redistribution structure 200. According to embodiments, the mark metal layer 260 may be provided at substantially the same vertical level as the upper pads 240. The mark metal layer 260 may include a material selected from the group consisting of nickel (Ni), aluminum (Al), iron (Fc), copper (Cu), titanium (Ti), chromium (Cr), gold (Au), silver (Ag), palladium (Pd), and platinum (Pt). The mark metal layer 260 may be provided on an upper side of the first semiconductor chip 300. The mark metal layer 260 may overlap the first semiconductor chip 300 in the vertical direction (Z-axis direction).

The mark metal layer 260 may include a plurality of sub-metal layers in a cross-section thereof. The mark metal layer 260 may include a first sub-metal layer 261, a second sub-metal layer 262, and a third sub-metal layer 263. The first sub-metal layer 261, the second sub-metal layer 262, and the third sub-metal layer 263 may be a copper layer, a nickel layer, and a gold layer, respectively. Other metals can be selected having a visual contrast between upper layer 261 and the exposed layer 263. The contrast can be a difference in shade, color, reflectivity, etc. to allow a person to view or a scanner, camera, or other electronics to capture the mark 265.

The mark 265 may be provided on an upper surface of the mark metal layer 260. As shown in FIG. 4, the mark 265 may include letters, numbers, an identification code, or the like to provide various pieces of information about the semiconductor package 10. The letters may include a product logo or a manufacturer's serial number. The identification code may include a 2D bar code and a QR code. The mark 265 may be understood as a pattern 268 formed on the upper surface of the mark metal layer 260. The mark 265 may be a pattern 268 in a cross-section (cross-sectional view) that is formed through ablation by a laser beam applied to the mark metal layer 260. In other words, the mark 265 may be a cross-sectional pattern 268 formed by applying a laser beam to the mark metal layer 260 to melt and evaporate a portion of the mark metal layer 260. The pattern 268 forming the mark 265 may have a depth of about 0.1 μm to 5 μm in the vertical direction (Z-axis direction). However, the depth of the pattern 268 in the vertical direction (Z-axis direction) is not limited to the range.

The mesh metal layer 250 may be provided on a lower portion of the mark metal layer 260. The mesh metal layer 250 may be in physical contact with a lower surface of the mark metal layer 260. As shown in FIG. 5, the mesh metal layer 250 may include at least one hole H extending in the vertical direction (Z-axis direction). According to embodiments, a cross-section of the hole H taken along the X-Y plane may have a square shape. However, the shape of the hole H is not limited thereto, and the cross-section of the hole H taken along the X-Y plane may have a circular or polygonal shape. Also, the metal layer 250 can have a lattice or grid type structure, a series of channels, or another layout of alternating metal and empty space areas.

In some embodiments, the second redistribution insulating layer 210 may not be provided in the hole H of the mesh metal layer 250. That is, the hole H of the mesh metal layer 250 may be an empty space. In some embodiments, the second redistribution insulating layer 210 may be provided in the hole H of the mesh metal layer 250. In this case, the second redistribution insulating layer 210 provided in the hole H of the mesh metal layer 250 may have a shape extending in the vertical direction (Z-axis direction).

According to embodiments, the mesh metal layer 250 may have the same overall shape as the mark metal layer 260 when viewed from above in the vertical direction (Z-axis direction). For example, when a cross-section of the mark metal layer 260 taken along the X-Y plane has a tetragonal shape, the mesh metal layer 250 may have a tetragonal shape when viewed from above in the vertical direction (Z-axis direction). A lateral surface of the mesh metal layer 250 may be on the same plane as a lateral surface of the mark metal layer 260.

A heat-conducting via 255 extending in the vertical direction (Z-axis direction) may be provided on a lower surface of the mesh metal layer 250. The heat-conducting vias 255 may not overlap the hole H of the mesh metal layer 250 in the vertical direction (Z-axis direction). The heat-conducting via 255 may be in physical contact with the lower surface of the mesh metal layer 250. The heat-conducting via 255 may penetrate an uppermost layer of the plurality of layers of the second redistribution insulating layer 210 in the vertical direction (Z-axis direction). A plurality of heat-conducting vias 255 may be provided. Each of the plurality of heat-conducting vias 255 may physically connect the mesh metal layer 250 and the second redistribution pattern 230 to each other. For example, the heat-conducting vias 255 may physically connect the mesh metal layer 250 and the second redistribution line pattern 233 to each other. Here, the second redistribution line pattern 233 physically connected to the mesh metal layer 250 through the heat-conducting vias 255 may be provided at a vertical level lower than the vertical level of the upper pads 240. According to embodiments, each of the heat-conducting vias 255 may overlap the mesh metal layer 250 in the vertical direction (Z-axis direction).

In the semiconductor package 10 of the inventive concept, the mesh metal layer 250 may be provided on a lower portion of the mark metal layer 260 provided on the upper surface of the second redistribution structure 200. The mesh metal layer 250 may include at least one hole H extending in the vertical direction (Z-axis direction). At least one hole H formed in the mesh metal layer 250 may be used as a path through which gas generated when the second redistribution insulating layer 210 hardens is discharged.

In the related art, the mark metal layer 260 is provided on the second redistribution insulating layer 210, and thus, the flow of gas generated when the second redistribution insulating layer 210 hardens may be limited by the mark metal layer 260. In the semiconductor package 10 of the inventive concept, however, the mesh metal layer 250 may be provided on the lower surface of the mark metal layer 260, and the second redistribution insulating layer 210 may be provided on the lower surface of the mesh metal layer 250. Therefore, gas generated as the second redistribution insulating layer 210 hardens may be discharged to the outside through the hole H of the mesh metal layer 250. Before the mark metal layer 260 is disposed on an upper surface of the mesh metal layer 250, gas generated as the second redistribution insulating layer 210 hardens may be discharged to the outside through the hole H of the mesh metal layer 250.

Furthermore, in the semiconductor package 10 of the inventive concept, at least one heat-conducting via 255 extending in the vertical direction (Z-axis direction) is provided on the lower surface of the mesh metal layer 250. Because the heat-conducting via 255 is physically connected to the second redistribution pattern 230, heat generated in the semiconductor package 10 may be dissipated to the outside more efficiently. For example, heat generated from the first semiconductor chip 300 may be dissipated to the outside through the first molding member 390, the second redistribution pattern 230, the heat-conducting via 255, the mesh metal layer 250, and the mark metal layer 260. Therefore, the thermal characteristics of the semiconductor package 10 may be improved.

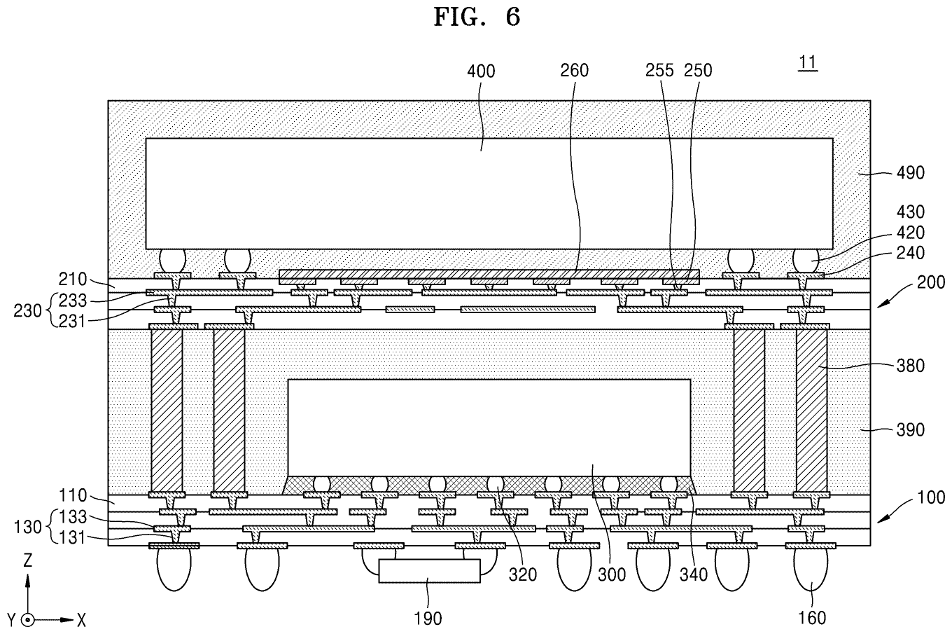

FIG. 6 is a cross-sectional view illustrating a semiconductor package 11 according to an embodiment. In the following description of the semiconductor package 11 shown in FIG. 6, the same characteristics as the characteristics of the semiconductor package 10 described with reference to FIGS. 1 to 5 are not described, and differences are mainly described.

Referring to FIG. 6, the semiconductor package 11 may include a first redistribution structure 100, a first semiconductor chip 300, a first molding member 390, a second redistribution structure 200, a mesh metal layer 250, a mark metal layer 260, a second semiconductor chip 400, and a second molding member 490.

The first redistribution structure 100 may be disposed below the first semiconductor chip 300 and may electrically connect the first semiconductor chip 300 to the external connection bumps 160. The first redistribution structure 100 may include a first redistribution insulating layer 110 and a first redistribution pattern 130. The external connection bumps 160 may be provided on a lower portion of the first redistribution structure 100. The external connection bumps 160 may be electrically connected to an external device, for example, a motherboard. A passive device 190 may be disposed below the first redistribution structure 100 apart from the external connection bumps 160 in a first horizontal direction (X-axis direction). According to embodiments, the passive device 190 may be connected to the first redistribution structure 100 through bumps. The first semiconductor chip 300 may be mounted on an upper surface of the first redistribution structure 100. The first semiconductor chip 300 may be electrically connected to the first redistribution pattern 130.

The first molding member 390 may be formed on the upper surface of the first redistribution structure 100 to surround the first semiconductor chip 300. A conductive pillar 380 may be disposed on the upper surface of the first redistribution structure 100 apart from the first semiconductor chip 300 in a horizontal direction. According to embodiments, a plurality of conductive pillars 380 may be provided. The plurality of conductive pillars 380 may be arranged apart from each other at predetermined intervals in the horizontal direction. The conductive pillars 380 may electrically connect the second redistribution structure 200 and the first redistribution structure 100 to each other.

The second redistribution structure 200 may be disposed on an upper surface of the first molding member 390. The second redistribution structure 200 may electrically connect conductive bumps 420 and the conductive pillars 380 to each other. The second redistribution structure 200 may include a second redistribution pattern 230, a second redistribution insulating layer 210, and upper pads 240.

The mark metal layer 260 may be provided on an upper surface of the second redistribution structure 200. According to embodiments, the mark metal layer 260 may be provided at substantially the same vertical level as the upper pads 240. A mark 265 may be provided on an upper surface of the mark metal layer 260. The mesh metal layer 250 may be provided on a lower portion of the mark metal layer 260. The mesh metal layer 250 may be in physical contact with a lower surface of the mark metal layer 260. The mesh metal layer 250 may include at least one hole H extending in a vertical direction (Z-axis direction). Heat-conducting vias 255 extending in the vertical direction (Z-axis direction) may be provided on a lower surface of the mesh metal layer 250. The heat-conducting vias 255 may not overlap the hole H of the mesh metal layer 250 in the vertical direction (Z-axis direction). The heat-conducting vias 255 may be in physical contact with the lower surface of the mesh metal layer 250.

The second semiconductor chip 400 may be mounted on the upper surface of the second redistribution structure 200. The second semiconductor chip 400 may be mounted on the second redistribution structure 200 by a flip chip method. The second semiconductor chip 400 may be electrically connected to the second redistribution structure 200 through conductive bumps 420. For example, the second semiconductor chip 400 may be electrically connected to the second redistribution structure 200 through the conductive bumps 420 and the upper pads 240. In this case, the upper pads 240 may not overlap the mark metal layer 260 in the vertical direction (Z-axis direction). In some embodiments, the conductive bumps 420 may be sealed by the second molding member 490. According to embodiments, the second semiconductor chip 400 may include a memory chip or a logic chip.

Although FIG. 6 illustrates that the footprint of the second semiconductor chip 400 is larger than the footprint of the first semiconductor chip 300, the footprint of the second semiconductor chip 400 is not limited thereto. For example, the footprint of the second semiconductor chip 400 may be substantially the same as the footprint of the first semiconductor chip 300 or may be smaller than the footprint of the first semiconductor chip 300.

The second molding member 490 may be provided on the second redistribution structure 200 to surround the second semiconductor chip 400. The second molding member 490 may cover at least a portion of the upper surface of the second redistribution structure 200.

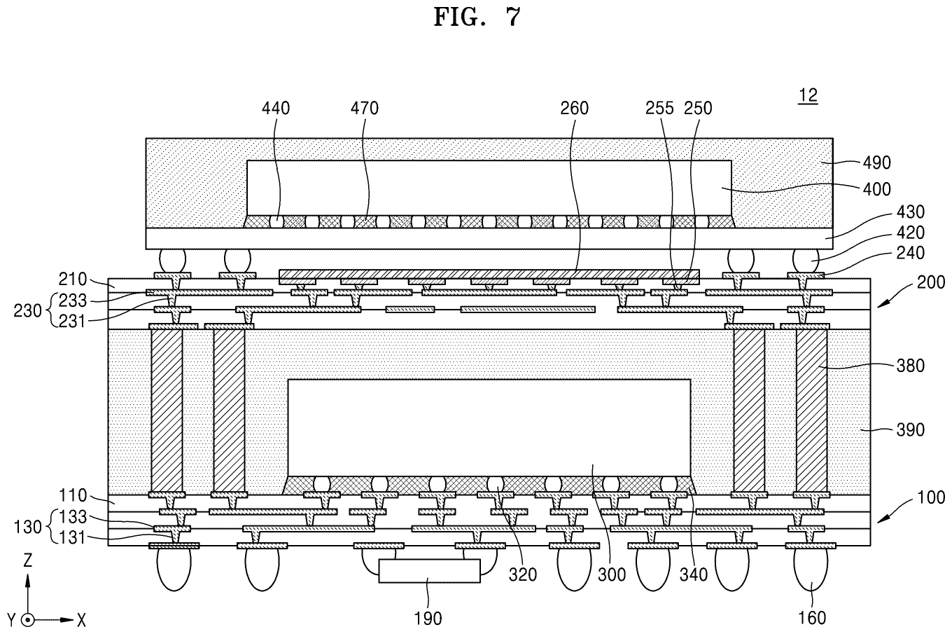

FIG. 7 is a cross-sectional view illustrating a semiconductor package 12 according to an embodiment. In the following description of the semiconductor package 12 shown in FIG. 7, the same characteristics as the characteristics of the semiconductor package 11 described with reference to FIG. 6 are not described, and differences are mainly described.

Referring to FIG. 7, the semiconductor package 12 may include a first redistribution structure 100, a first semiconductor chip 300, a first molding member 390, a second redistribution structure 200, a mesh metal layer 250, a mark metal layer 260, a substrate 430, a second semiconductor chip 400, and a second molding member 490.

The first redistribution structure 100 may be disposed below the first semiconductor chip 300 and may electrically connect the first semiconductor chip 300 to the external connection bumps 160. The first redistribution structure 100 may include a first redistribution insulating layer 110 and a first redistribution pattern 130. The external connection bumps 160 may be provided on a lower portion of the first redistribution structure 100. The external connection bumps 160 may be electrically connected to an external device, for example, a motherboard. A passive device 190 may be disposed below the first redistribution structure 100 apart from the external connection bumps 160 in a first horizontal direction (X-axis direction). According to embodiments, the passive device 190 may be connected to the first redistribution structure 100 through bumps. The first semiconductor chip 300 may be mounted on an upper surface of the first redistribution structure 100. The first semiconductor chip 300 may be electrically connected to the first redistribution pattern 130.

The first molding member 390 may be formed on the upper surface of the first redistribution structure 100 to surround the first semiconductor chip 300. A conductive pillar 380 may be disposed on the upper surface of the first redistribution structure 100 apart from the first semiconductor chip 300 in a horizontal direction. According to embodiments, a plurality of conductive pillars 380 may be provided. The plurality of conductive pillars 380 may be arranged apart from each other at predetermined intervals in the horizontal direction. The conductive pillars 380 may electrically connect the second redistribution structure 200 and the first redistribution structure 100 to each other.

The second redistribution structure 200 may be disposed on an upper surface of the first molding member 390. The second redistribution structure 200 may electrically connect conductive bumps 420 and the conductive pillars 380 to each other. The second redistribution structure 200 may include a second redistribution pattern 230, a second redistribution insulating layer 210, and upper pads 240.

The mark metal layer 260 may be provided on an upper surface of the second redistribution structure 200. According to embodiments, the mark metal layer 260 may be provided at substantially the same vertical level as the upper pads 240. A mark 265 may be provided on an upper surface of the mark metal layer 260. The mesh metal layer 250 may be provided on a lower portion of the mark metal layer 260. The mesh metal layer 250 may be in physical contact with a lower surface of the mark metal layer 260. The mesh metal layer 250 may include at least one hole H extending in a vertical direction (Z-axis direction). Heat-conducting vias 255 extending in the vertical direction (Z-axis direction) may be provided on a lower surface of the mesh metal layer 250. The heat-conducting vias 255 may not overlap the hole H of the mesh metal layer 250 in the vertical direction (Z-axis direction). The heat-conducting vias 255 may be in physical contact with the lower surface of the mesh metal layer 250.

The substrate 430 on which the second semiconductor chip 400 is mounted may be disposed on the upper surface of the second redistribution structure 200. The substrate 430 may be formed based on, for example, a ceramic substrate, a PCB, or an organic substrate.

The substrate 430 may be electrically connected to the second redistribution structure 200 through the conductive bumps 420. For example, the substrate 430 may be electrically connected to the second redistribution structure 200 through the conductive bumps 420 and the upper pads 240.

The second semiconductor chip 400 may be connected to the substrate 430 through chip connection bumps 440. The second semiconductor chip 400 may be mounted on the second redistribution structure 200 by a flip chip method through the chip connection bumps 440, and the chip connection bumps 440 may be micro-bumps. According to embodiments, an underfill material layer 470 surrounding the chip connection bumps 440 may be disposed between the second semiconductor chip 400 and the second redistribution structure 200. For example, the underfill material layer 470 may be formed by a capillary underfill method using an epoxy resin. In some embodiments, however, the second molding member 490 may be directly filled in a gap between the second semiconductor chip 400 and the second redistribution structure 200 through a molded underfill process. In this case, the underfill material layer 470 may be omitted.

The second molding member 490 may seal the second semiconductor chip 400 mounted on the substrate 430. According to embodiments, a lateral surface of the second molding member 490 may be on the same plane as a lateral surface of the substrate 430. According to embodiments, an empty space may be provided between the substrate 430 and the mark metal layer 260.

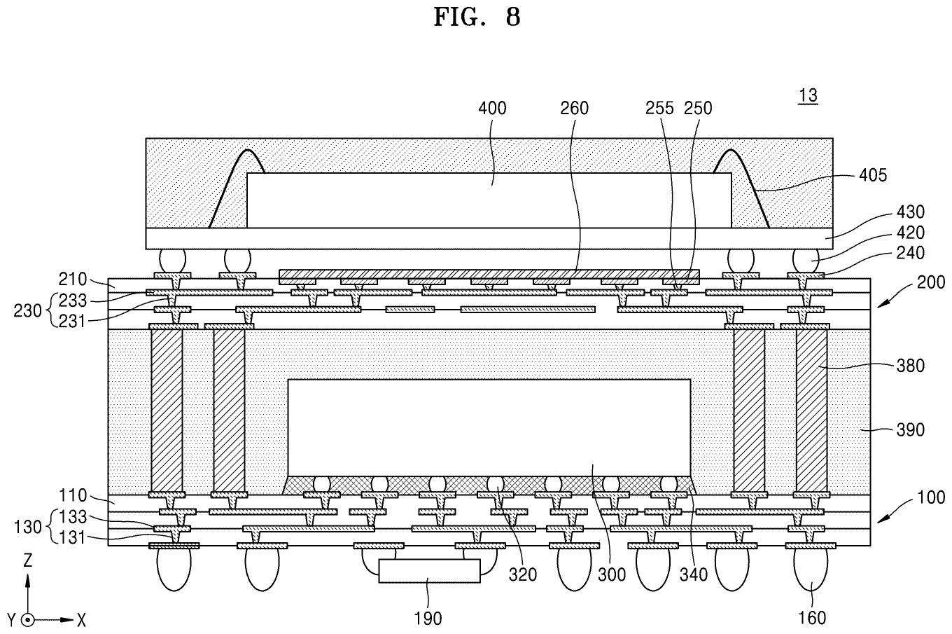

FIG. 8 is a cross-sectional view illustrating a semiconductor package 13 according to an embodiment. In the following description of the semiconductor package 13 shown in FIG. 8, the same characteristics as the characteristics of the semiconductor package 11 described with reference to FIG. 7 are not described, and differences are mainly described.

Referring to FIG. 8, the semiconductor package 13 may include a first redistribution structure 100, a first semiconductor chip 300, a first molding member 390, a second redistribution structure 200, a mesh metal layer 250, a mark metal layer 260, a substrate 430, a second semiconductor chip 400, and a second molding member 490. The first redistribution structure 100 may be disposed below the first semiconductor chip 300 and may electrically connect the first semiconductor chip 300 to the external connection bumps 160. The first redistribution structure 100 may include a first redistribution insulating layer 110 and a first redistribution pattern 130. The external connection bumps 160 may be provided on a lower portion of the first redistribution structure 100. The external connection bumps 160 may be electrically connected to an external device, for example, a motherboard. A passive device 190 may be disposed below the first redistribution structure 100 apart from the external connection bumps 160 in a first horizontal direction (X-axis direction). According to embodiments, the passive device 190 may be connected to the first redistribution structure 100 through bumps. The first semiconductor chip 300 may be mounted on an upper surface of the first redistribution structure 100. The first semiconductor chip 300 may be electrically connected to the first redistribution pattern 130.

The first molding member 390 may be formed on the upper surface of the first redistribution structure 100 to surround the first semiconductor chip 300. A conductive pillar 380 may be disposed on the upper surface of the first redistribution structure 100 apart from the first semiconductor chip 300 in a horizontal direction. According to embodiments, a plurality of conductive pillars 380 may be provided. The plurality of conductive pillars 380 may be arranged apart from each other at predetermined intervals in the horizontal direction. The conductive pillars 380 may electrically connect the second redistribution structure 200 and the first redistribution structure 100 to each other.

The second redistribution structure 200 may be disposed on an upper surface of the first molding member 390. The second redistribution structure 200 may electrically connect conductive bumps 420 and the conductive pillars 380 to each other. The second redistribution structure 200 may include a second redistribution pattern 230, a second redistribution insulating layer 210, and upper pads 240.

The mark metal layer 260 may be provided on an upper surface of the second redistribution structure 200. According to embodiments, the mark metal layer 260 may be provided at substantially the same vertical level as the upper pads 240. A mark 265 may be provided on an upper surface of the mark metal layer 260. The mesh metal layer 250 may be provided on a lower portion of the mark metal layer 260. The mesh metal layer 250 may be in physical contact with a lower surface of the mark metal layer 260. The mesh metal layer 250 may include at least one hole H extending in a vertical direction (Z-axis direction). Heat-conducting vias 255 extending in the vertical direction (Z-axis direction) may be provided on a lower surface of the mesh metal layer 250. The heat-conducting vias 255 may not overlap the hole H of the mesh metal layer 250 in the vertical direction (Z-axis direction). The heat-conducting vias 255 may be in physical contact with the lower surface of the mesh metal layer 250.

A substrate 430 on which the second semiconductor chip 400 is mounted may be disposed on the upper surface of the second redistribution structure 200. The substrate 430 may be formed based on, for example, a ceramic substrate, a PCB, or an organic substrate.

The substrate 430 may be electrically connected to the second redistribution structure 200 through the conductive bumps 420. For example, the substrate 430 may be electrically connected to the second redistribution structure 200 through the conductive bumps 420 and the upper pads 240.

The second semiconductor chip 400 may be connected to the substrate 430 through wires 405. In this case, the second semiconductor chip 400 may be disposed such that a wafer layer of the second semiconductor chip 400 may face the substrate 430. According to embodiments, the second semiconductor chip 400 may be fixed to the substrate 430 through an adhesive layer 480. The second molding member 490 may be formed on the substrate 430 to seal the second semiconductor chip 400 and the wires 405.

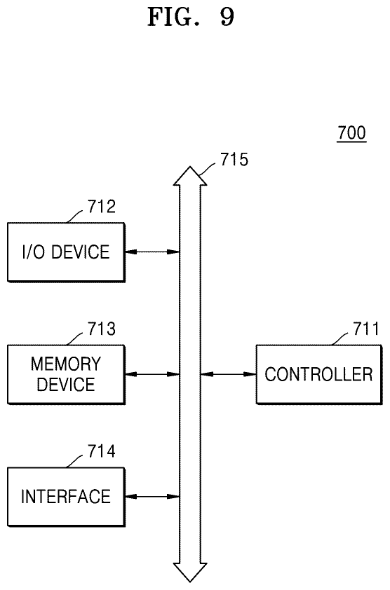

FIG. 9 is a schematic block diagram illustrating a memory system 700 as an example including a semiconductor package according to an embodiment.

For example, the memory system 700 may be applied to a personal digital assistant (PDA), a portable computer, a web tablet, a wireless phone, a mobile phone, a digital music player, a memory card, or any device capable of transmitting and/or receiving information in a wireless environment.

The memory system 700 includes a controller 711, an input/output (I/O) device 712 such as a keypad, a keyboard, or a display, a memory device (or memory chip) 713, an interface 714, and a bus 715. The memory device 713 and the interface 714 communicate with each other through the bus 715.

The controller 711 includes at least one microprocessor, a digital signal processor, a microcontroller, or other processing devices similar thereto. The memory device 713 may be used to store commands performed by the controller 711. The I/O device 712 may receive data or signals from the outside of the memory system 700 or output data or signals to the outside of the memory system 700. For example, the I/O device 712 may include a keyboard, a keypad, or a display.

The memory device 713 and the controller 711 may include any of the semiconductor packages 10 to 13 of the embodiments described above. The memory device 713 may further include other types of memory, volatile memory that may be accessed at any time, and various other types of memory. The interface 714 has a function of transmitting data to a communication network or receiving data from the communication network.

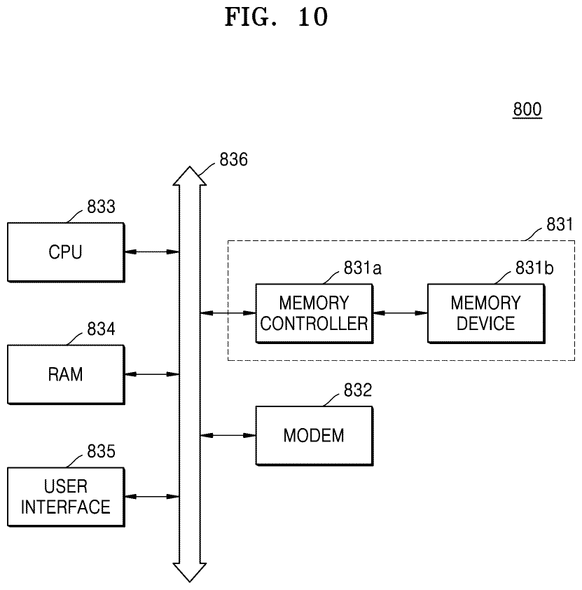

FIG. 10 is a schematic block diagram illustrating an information processing system 800 as an example including a semiconductor package according to an embodiment.

For example, the information processing system 800 may be used in a mobile device or a desktop computer. The information processing system 800 may include a memory system 831, and the memory system 831 may include a memory controller 831a and a memory device 831b.

The information processing system 800 includes a modem 832 (MOdulator and DEModulator: MODEM) electrically connected to a system bus 836, a central processing unit (CPU) 833, a random access memory (RAM) 834, and a user interface 835. Data processed by the CPU 833 or data input from the outside of the information processing system 800 is stored in the memory system 831.

The memory system 831 including the memory controller 831a and the memory device 831b, the modem 832, the CPU 833, and the RAM 834 may include any of the semiconductor packages 10 to 13 of the embodiments described above.

The memory system 831 may be configured as a solid state drive, and in this case, the information processing system 800 may stably store a large amount of data in the memory system 831. In addition, the memory system 831 may save resources required for error correction owing to improved reliability and may thus provide a high-speed data exchange function to the information processing system 830.

Although not shown in FIG. 10, it is apparent to those of ordinary skill in the art that the information processing system 800 may further include an application chipset, a camera image signal processor (ISP), an I/O device, or the like.

While the inventive concept has been particularly shown and described with reference to embodiments thereof, it will be understood that various changes in form and details may be made therein without departing from the spirit and scope of the following claims.

What is claimed is:

1. A semiconductor package comprising:
a first molding member covering at least one first semiconductor chip;
a redistribution structure provided on the first molding member and comprising a redistribution pattern, an upper pad, and a redistribution insulating layer;
a mark metal layer provided on the redistribution structure; and
a mesh metal layer provided on a lower surface of the mark metal layer and comprising at least one hole.

2. The semiconductor package of claim 1, wherein the mesh metal layer is provided on an upper portion of the redistribution insulating layer.

3. The semiconductor package of claim 1, wherein the redistribution structure further comprises a heat-conducting via that physically connects the mesh metal layer and the redistribution pattern to each other.

4. The semiconductor package of claim 3, wherein the heat-conducting via has a shape extending in a vertical direction.

5. The semiconductor package of claim 3, wherein the redistribution insulating layer comprises a plurality of redistribution insulating layers stacked in a vertical direction, and
the heat-conducting via is formed in an uppermost redistribution insulating layer among the plurality of redistribution insulating layers stacked in the vertical direction.

6. The semiconductor package of claim 1, wherein each of the mesh metal layer and the mark metal layer is provided on an upper side of the at least one first semiconductor chip.

7. The semiconductor package of claim 1, wherein the upper pad is provided on an upper surface of the redistribution structure and is apart from the mark metal layer in a horizontal direction.

8. The semiconductor package of claim 7, further comprising:
a second semiconductor chip provided on the redistribution structure;
a conductive bump connecting the second semiconductor chip and the upper pad to each other; and
a second molding member provided on the redistribution structure and surrounding the second semiconductor chip.

9. The semiconductor package of claim 7, further comprising:
a substrate provided on the redistribution structure;
a conductive bump connecting the substrate and the upper pad to each other;
a second semiconductor chip mounted on the substrate;
a chip connection bump connecting the second semiconductor chip and the substrate to each other; and
a second molding member surrounding the second semiconductor chip.

10. The semiconductor package of claim 7, further comprising:
a substrate provided on the redistribution structure;
a conductive bump connecting the substrate and the upper pad to each other;
a second semiconductor chip mounted on the substrate;
a wire connecting the second semiconductor chip and the substrate to each other; and
a second molding member surrounding the second semiconductor chip.

11. The semiconductor package of claim 1, further comprising a conductive pillar penetrating the first molding member in a vertical direction.

12. A semiconductor package comprising:
a first redistribution structure comprising a first redistribution pattern configured to transmit an electrical signal, and a first redistribution insulating layer surrounding the first redistribution pattern;
a first semiconductor chip mounted on the first redistribution structure;
a first molding member surrounding the first semiconductor chip;
a second redistribution structure comprising a second redistribution pattern configured to transmit an electrical signal, a second redistribution insulating layer surrounding the second redistribution pattern, and an upper pad exposed upward on the second redistribution insulating layer in a vertical direction, the second redistribution structure being provided on an upper surface of the first molding member;
a mark metal layer provided on the second redistribution structure;
a mesh metal layer provided on a lower surface of the mark metal layer and comprising at least one hole; and
a heat-conducting via provided on a lower surface of the mesh metal layer and physically connecting the mesh metal layer and the second redistribution pattern to each other.

13. The semiconductor package of claim 12, wherein a mark comprising at least one selected from the group consisting of letters, numbers, and identification codes is formed on an upper surface of the mark metal layer.

14. The semiconductor package of claim 12, wherein each of the mesh metal layer and the mark metal layer overlaps the first semiconductor chip in the vertical direction.

15. The semiconductor package of claim 12, wherein the upper pad is provided on an upper surface of the second redistribution structure and is apart from the mark metal layer in a horizontal direction.

16. The semiconductor package of claim 15, further comprising:
a second semiconductor chip provided on the second redistribution structure;
a conductive bump connecting the second semiconductor chip and the upper pad to each other; and
a second molding member surrounding the second semiconductor chip,
wherein the second molding member covers at least a portion of the upper surface of the second redistribution structure.

17. The semiconductor package of claim 15, further comprising:
a substrate provided on the second redistribution structure;
a conductive bump connecting the substrate and the upper pad to each other;
a second semiconductor chip mounted on the substrate; and
a second molding member provided on the substrate and surrounding the second semiconductor chip.

18. A semiconductor package comprising:
a first redistribution structure comprising a first redistribution pattern configured to transmit an electrical signal, and a first redistribution insulating layer surrounding the first redistribution pattern;
a first semiconductor chip mounted on the first redistribution structure;
a conductive pillar provided on the first redistribution structure and apart from the first semiconductor chip in a horizontal direction;
a first molding member surrounding each of the first semiconductor chip and the conductive pillar;
a second redistribution structure comprising a second redistribution pattern configured to transmit an electrical signal, a second redistribution insulating layer surrounding the second redistribution pattern, and an upper pad exposed upward on the second redistribution insulating layer in a vertical direction, the second redistribution structure being provided on an upper surface of the first molding member;
a mark metal layer provided on the second redistribution structure and comprising a mark on an upper surface thereof, the mark comprising at least one selected from the group consisting of letters, numbers, and identification codes;
a mesh metal layer provided on a lower surface of the mark metal layer and comprising at least one hole; and
a heat-conducting via provided on a lower surface of the mesh metal layer and physically connecting the mesh metal layer and the second redistribution pattern to each other,
wherein the second redistribution insulating layer comprises a plurality of second redistribution insulating layers stacked in the vertical direction, and the heat-conducting via is formed in an uppermost second redistribution insulating layer among the plurality of second redistribution insulating layers,
wherein each of the mesh metal layer and the mark metal layer overlaps the first semiconductor chip in the vertical direction.

19. The semiconductor package of claim 18, wherein the upper pad is provided on an upper surface of the second redistribution structure and is apart from the mark metal layer in the horizontal direction.

20. The semiconductor package of claim 18, further comprising:
a substrate provided on the second redistribution structure;
a conductive bump connecting the substrate and the upper pad to each other;
a second semiconductor chip mounted on the substrate; and
a second molding member provided on the substrate and surrounding the second semiconductor chip.
